(19) United States
(12) Patent Application Publication
(10) Pub. No.: US 2010/0163830 A1
(43) Pub. Date: Jul. 1, 2010

(54) PHASE-CHANGE RANDOM ACCESS MEMORY CAPABLE OF REDUCING THERMAL BUDGET AND METHOD OF MANUFACTURING THE SAME

(76) Inventors: Heon Yong CHANG, Gyeonggi-do (KR); Keum Bum LEE, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/493,410

(22) Filed: Jun. 29, 2009

(30) Foreign Application Priority Data
Dec. 26, 2008 (KR) 10-2008-0134271

(51) Int. Cl. H01L 45/00; H01L 21/06

(52) U.S. Cl. 257/3; 438/102; 257/E45.002; 257/E21.068

(57) ABSTRACT

A phase-change random access memory (PRAM) is presented which can ensure the integrity of the electrical characteristics of driving transistors even when the PRAM is with a high temperature SEG fabrication process because the fabrication time is minimized. A method of manufacturing the PRAM includes the following steps. After preparing a semiconductor substrate having a cell area and a peripheral area, a junction area is formed in the cell area. Then, a transistor having a gate electrode with a single conductive layer is formed in the peripheral area. Subsequently, a first interlayer dielectric layer is formed at an upper portion of the semiconductor substrate, and then a contact hole is formed by etching the first interlayer dielectric layer to expose a predetermined portion of the junction area. Next, an epitaxial layer is grown in the contact hole.

### CROSS-REFERENCES TO RELATED APPLICATION

The present application claims priority under 35 U.S.C. 119(a) to Korean application number 10-2008-0134271, filed on Dec. 26, 2008, in the Korean Patent Office, which is incorporated by reference in its entirety as if set forth in full.

### BACKGROUND OF THE INVENTION

1. Technical Field

The embodiments described herein relate to a phase-change random access memory and a method of manufacturing the same, and, more particularly, to a phase-change random access memory capable of reducing thermal budget and a method of the same.

2. Related Art

A phase-change random access memory (PRAM) stores data by using phase-change materials that reversibly interconvert between various solid state phases. A popularly form of phase-change materials do this by reversibly interconverting between an organized crystalline solid state and an disorganized amorphous solid state when heats and subsequently anneals the phase-change materials in the PRAM. The organized crystalline solid state usually exhibits a lower resistance than the disorganized amorphous solid state of the phase-change materials. As a result of this differential change in physical properties, i.e. a change in the resistance as a function of which solid state phase, then these types of phase-change materials can be exploited as storage media in memory devices. A popular phase-change materials often includes chalcogenide materials such as GST (GeSbTe).

Such a PRAM may include a plurality of phase-change memory cells formed along intersection regions of word lines and bit lines. Each phase-change memory cell can include a resistor having a value varied according to a through current and an access element controlling a current applied to the resistor. The access element can include those selected from the group consisting of a PNP bipolar transistor, an MOS transistor, or a PN diode. Recently, the PN diode occupying a narrow region is mainly employed as the access element of a highly-integrated PRAM.

The PN diode can be obtained by using a selective epitaxial growth (SEG) growth of an silicon epitaxial layer at a predetermined height coupled with a subsequent implantation of predetermined amounts of impurities can into the silicon epitaxial layer. In this case, the epitaxial layer is grown to the height of a gate electrode formed in a peripheral area. In more detail, after growing the epitaxial layer to the height greater or equal to the height of the gate electrodes of the peripheral area, the epitaxial layer is then planarized to the match the height of the gate electrodes. Accordingly, the epitaxial layer for the PN diode is fabricated to match the height of the gate electrode.

Unfortunately, the SEG scheme is a thermal process which requires a temperature of about 700° C. Accordingly, because of this thermal burden the SEG process can significantly add to the thermal budget. In other words, processing a chip beyond its thermal budget may compromise the electrical characteristics of the resulting chip which includes unwittingly altering the electrical characteristics of components such as existing transistors in the peripheral area.

This thermal budget problem can arise in PRAM manufacturing because the epitaxial layer for the PN diode of the PRAM is grown after fabricating driving transistors in the peripheral area. As a result a subsequent high-temperature epitaxial process forming the epitaxial layer to the desired height coupled with the impurity profile processing to eventually build the access element then unwanted deleterious effects at other electronic components may arise. Some of these unwanted deleterious effects may be unwanted impurity diffusion occurring at the source-drain area which substantially changes the electrical characteristics of the gate electrode of the existing driving transistors. As a result of building the PRAM components, the driving characteristics of the PRAM may end up being compromised.

This problem may be further aggravated because of the demands of increasing the integration density of the PRAM. That is, the design rule of transistors formed in the peripheral area is restricted. For this reason, in order to maintain constant conductivity, the gate electrode is formed by stacking a plurality of conductive layers which causes the height of the gate electrode to increase. Accordingly, the processing time needed to grow the epitaxial layer is likely to be further increased and as a result the characteristic of the driving transistors can be compromised.

### SUMMARY

A phase-change random access memory capable of improving a driving characteristic is described herein.

A method of manufacturing the phase-change random access memory capable of ensuring the characteristics of a driving transistor by reducing the time taken to perform a high-temperature process is described herein.

According to one embodiment, a method of manufacturing a phase-change random access memory is performed as follows. After preparing a semiconductor substrate defining a cell area and a peripheral area, a junction area is formed in the cell area. Thereafter, a transistor having a gate electrode including a single conductive layer is formed in the peripheral area, and a first interlayer dielectric layer is formed at an upper portion of the semiconductor substrate. Then, after forming a contact hole by etching the first interlayer dielectric layer such that a predetermined portion of the junction area is exposed, an epitaxial layer is grown in the contact hole.

According to another embodiment, in a method of manufacturing a phase-change memory device, after preparing a semiconductor substrate defining a cell area and a peripheral area, a junction area is formed in the cell area. Then, after forming a transistor having a gate electrode including a single conductive layer in the peripheral area, a first interlayer dielectric layer is formed at an upper portion of the semiconductor substrate. Next, after forming a contact hole by etching the first interlayer dielectric layer such that a predetermined portion of the junction area is exposed, an epitaxial layer is grown such that the contact hole is filled with the epitaxial layer. Thereafter, the epitaxial layer and the first interlayer dielectric layer are planarized such that a surface of the gate electrode is exposed. A PN diode is formed in the epitaxial layer filled in the contact hole, and then an ohmic contact layer is formed on the PN diode and a conductivity compensating layer is formed on the gate electrode by forming a silicide layer on the PN diode and the gate electrode.

According to still another embodiment, a phase-change random access memory includes a semiconductor substrate, a word line area, a transistor, and a PN diode. The semiconductor substrate defines a cell area and a peripheral area, and the junction area is formed in the cell area of the semiconductor substrate. The transistor includes a gate electrode having a predetermined height and formed in the peripheral area of the semiconductor substrate, and a PN diode is electrically connected with the word line area. In this case, the gate electrode includes a single conductive layer, and has a height identical to that of the PN diode.

These and other features and embodiments are described below in the section entitled “Detailed Description.”

### BRIEF DESCRIPTION OF THE DRAWINGS

It is understood herein that the drawings are not necessarily to scale and in some instances proportions may have been exaggerated in order to more clearly depict certain features of the invention. The above and other aspects, features and other advantages of the subject matter of the present disclosure will be more clearly understood from the following detailed description taken in conjunction with the accompanying drawings, in which:

FIGS. 1 to 8 are sectional views showing a method of manufacturing a phase-change random access memory according to an embodiment of the present invention; and

FIGS. 9 to 10 are sectional views showing a method of manufacturing a phase-change random access memory according to another embodiment of the present invention.

### DETAILED DESCRIPTION

Hereinafter, a preferred embodiment of the present invention will be described with reference to accompanying drawings.

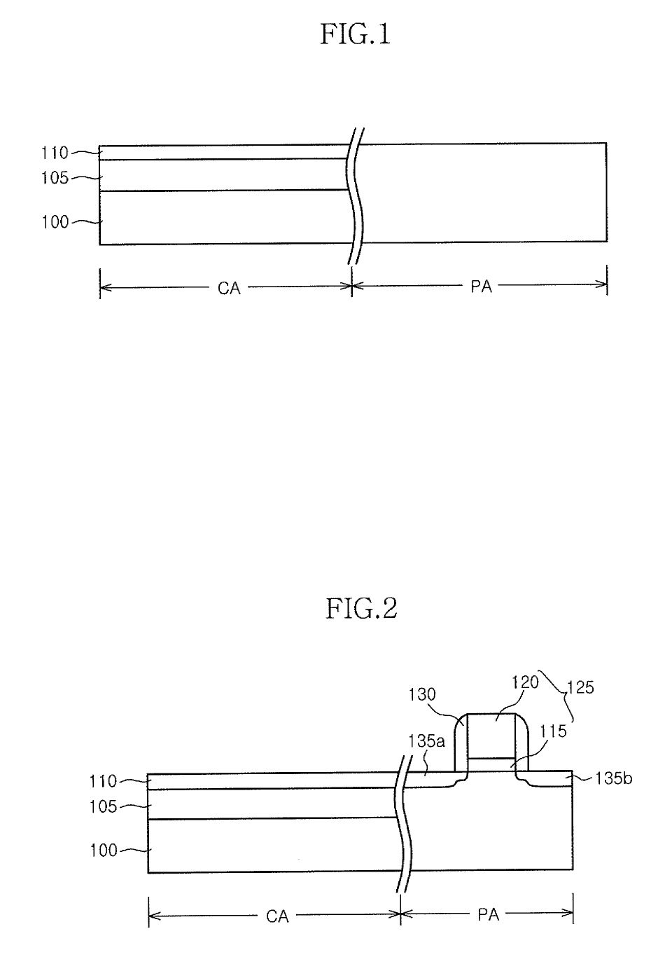

Referring to FIG. 1, a semiconductor substrate 100 defining a cell area CA and a peripheral area PA is prepared. Next, p-type impurities are deep ion-implanted into the cell area CA of the semiconductor substrate 100, thereby forming a p-well 105. Next, n-type impurities are ion-implanted into an upper portion of the p-well 105, thereby forming a junction area 110 that can subsequently function as a word line. In this case, the junction area 110 may be formed by ion-implanting n-type impurities such as phosphorus (P) or arsenic (As) with the density of between about 10²⁰/cm³ to 10²²/cm³ by using an ion-implanting energy of about 10 KeV to 100 KeV.

Subsequently, referring to FIG. 2, after sequentially stacking a gate insulating layer 115 and a gate conductive layer 120 on the peripheral area PA, a predetermined portion of the gate conductive layer 120 (or both the gate conductive layer 120 and the gate insulating layer 115) is patterned to form the gate electrode 125. In this case, the gate conductive layer 120 serves as a single conductive layer such as a doped polysilicon layer. In addition, the gate conductive layer 120 may be as thick as a main conductive layer (or a first conductive layer) provided at an upper portion of a gate insulating layer in a gate electrode having a conventional stack structure. Thereafter, insulating spacers 130 are formed at sidewalls of the gate electrode 125 through a scheme generally known to those skilled in the art such that junction areas (source/drain areas) having a lightly doped density (LDD) can be formed at the sidewalls. Next, impurities are implanted into the semiconductor substrate 100 at both sides of the gate electrode 125 to form the source and drain areas 135a and 135b having the LDD. As a result transistors are formed in the peripheral area PA.

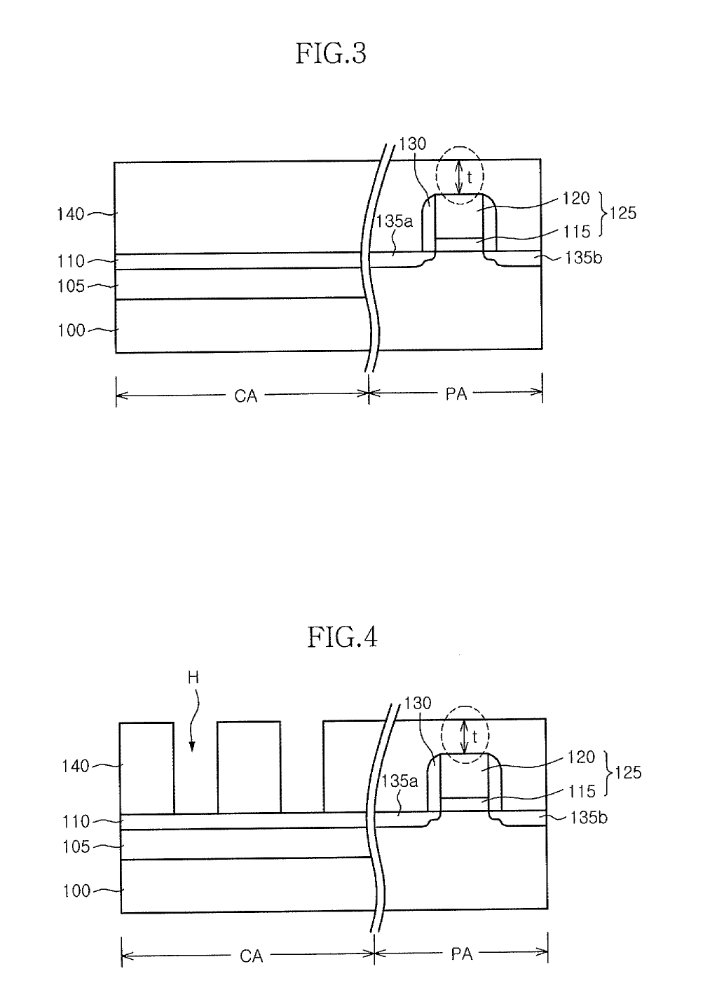

Referring to FIG. 3, a first interlayer dielectric layer 140 is deposited at an upper portion of the resultant structure of the semiconductor substrate 100 provided at the peripheral area PA thereof with the transistor. The first interlayer dielectric layer 140 may be formed higher than the gate electrode 120 by a predetermined thickness (t) (for example, a thickness of 100 Å to 2000 Å). In this case, since the gate electrode 120 according to the embodiment can be formed lower than a conventional gate electrode as described above, the first interlayer dielectric layer 140 can be formed lower than a conventional interlayer dielectric layer.

As shown in FIG. 4, a predetermined portion of the first interlayer dielectric layer 140 is selectively etched to form a contact hole H such that a predetermined portion of the junction area 110 in the cell area CA can be exposed. The location of the contact hole H is chosen to be at an area for a PN diode.

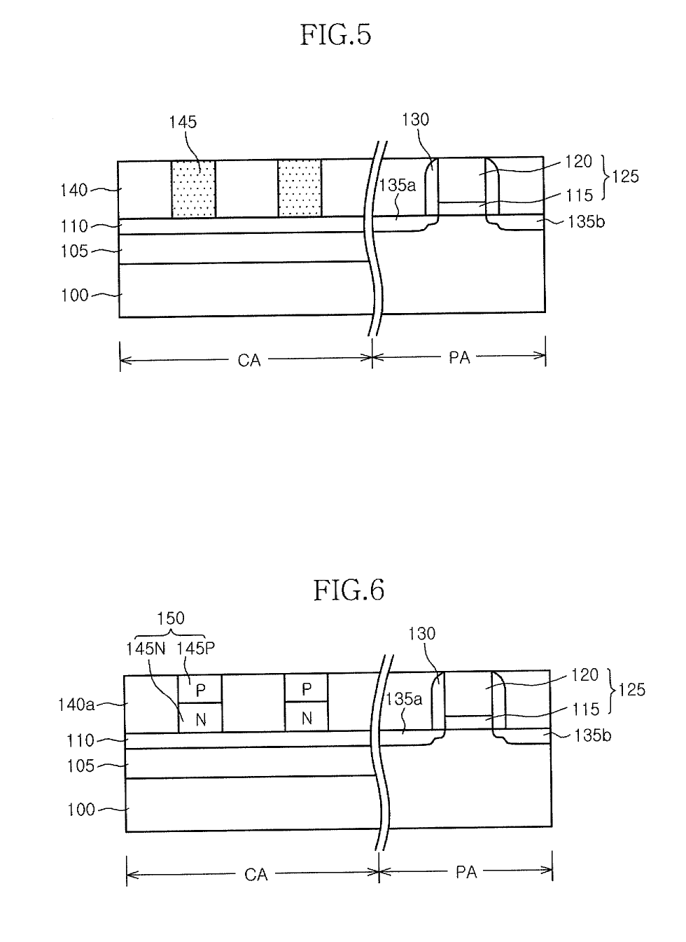

Referring to FIG. 5, an epitaxial layer is formed using a SEG fabrication scheme such that the contact hole H is sufficiently filled in with the epitaxial layer. The epitaxial layer may be a silicon layer that is not doped with impurities, and may be formed higher than the first interlayer dielectric layer 140 by a thickness of about 10 Å to 2000 Å such that the contact hole H is sufficiently filled with the epitaxial layer.

In this case, since the first interlayer dielectric layer 140 is formed lower than the conventional interlayer dielectric layer as described above, even if the epitaxial layer is grown shallower than the conventional epitaxial layer, the contact hole H can still be sufficiently filled in with the epitaxial layer. Accordingly, the SEG processing time can be reduced.

Thereafter, a planarization process, for example, a chemical mechanical polishing (CMP) process is performed such that the epitaxial layer remains only in the contact hole H to thereby form an epitaxial plug 145 within the contact hole H. Accordingly, the epitaxial plug 145 has a height substantially identical to that of the gate electrode 125. In this case, reference numeral 140a represents a first interlayer dielectric layer that has been subject to the planarization process.

Subsequently, referring to FIG. 6, n-type impurities are implanted into a lower portion of the epitaxial plug 145, thereby forming an n-type diode area 145N. The n-type diode area 145N may be formed by implanting ions of phosphorus (P) or arsenic (As) at a dopant density of between about 10¹⁸/cm³ to 10²⁰cm³ by using ion-implantation energies of between about 30 KeV to 100 KeV. Thereafter, p-type impurities are implanted into an upper portion of the epitaxial plug 145 to form a p-type diode area 145P to thereby form a PN diode 150. In this case, the p-type diode area 145P may be formed by implanting p-type impurities such as boron (B) or borondifluoride (BF₂) with a dopant density of between about 10²⁰/cm³ to 10²²/cm³ by using an ion-implantation energy of between about 10 KeV to 80 KeV. In addition, the n-type diode area 145N may be provided for the purpose of preventing a high electric field from being generated due to a difference in impurity density between the junction area 110 and the p-type diode area 145P.

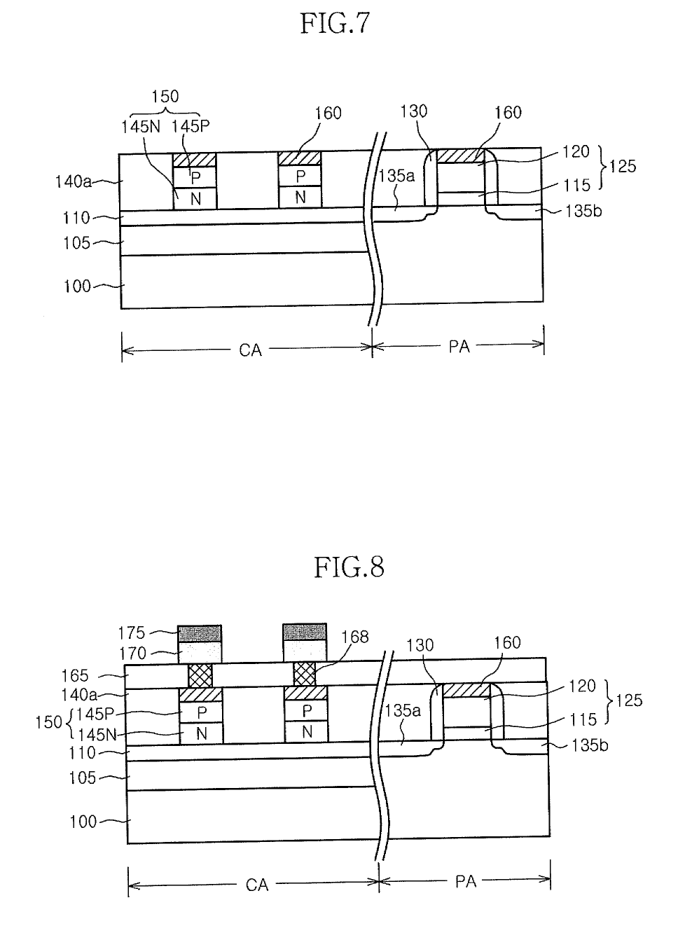

Referring to FIG. 7, a refractory metal layer such as those including copper (Co), titanium (Ti), or nickel (Ni) is deposited at a predetermined thickness on the first interlayer dielectric layer 140a having the PN diode 150. Next, the resultant structure of the semiconductor substrate 100 on which the refractory metal layer has been deposited is then subjected to heat-treatment under a predetermined temperature, so that the PN diode 150 and the gate electrode 125 including silicon existing on the surface of the resultant structure of the semiconductor substrate 100 react with the refractory metal layer. Accordingly, a silicide layer 160 is formed on the surface of the PN diode 150 and the gate electrode 125. Thereafter, the refractory metal layer that does not participate in the above reaction is removed using any number of removal schemes generally known to those skilled in the art. In this case, the refractory metal layer may have a thickness sufficient to form the silicide layer 160 having a thickness of between about 100 Å to 1000 Å. The silicide layer 160 formed on the PN diode 150 may serve as an ohmic contact layer relative to a heating electrode that is later formed. The silicide layer 160 formed on the gate electrode 125 may compensate for the conductivity of the gate electrode 125. Accordingly, without an additional process, the conductive characteristic of the gate electrode 125 can be compensated while the ohmic contact layer of the PN diode 150 is being formed. When the silicide layer 160 is formed, since the PN diode 150 and the gate conductive layer 120 serve as reactants, the silicide layer 160 that is a final resultant structure may have a surficial height substantially matching that of the first interlayer dielectric layer 140a.

Thereafter, referring to FIG. 8, a second interlayer dielectric layer 165 is deposited at an upper portion of the resultant structure of the semiconductor substrate 100. The second interlayer 165 may include a silicon nitride layer having superior heat resistance. The second interlayer dielectric layer 165 is formed thinner than the first interlayer dielectric layer 140a. Thereafter, a predetermined portion of the second interlayer dielectric layer 165 is etched such that the silicide layer 160 (i.e., an ohmic contact layer) on the PN diode 150 is exposed, thereby forming a through hole (not shown). The through hole may have a diameter smaller than that of the PN diode 50. For example, the through hole may have a diameter of about 10 nm to 10 nm. Next, a conductive layer having high resistivity is used to fill in the through hole to thereby form a heating electrode 168. Subsequently, a phase-change layer 170 and an upper electrode 175 are sequentially deposited on the second interlayer dielectric layer 165 having the heating electrode 168, and the resultant structure is patterned to thereby form a phase-change random access memory. The phase-change layer 170 and the upper electrode 175 may be patterned perpendicularly to the junction area 110. This is necessary to cause volume change at a central portion of the phase-change layer 170 by reducing etch loss in edges of the phase-change layer 170. Accordingly, since heat transferred to the phase-change layer 170 is not radiated to an exterior, the programming current can be lowered. In this case, a chalcogenide material including at least one of germanium (GE), antimony (Sb), and tellurium (Te) may be used for the phase-change layer 170. Such a phase-change layer 170 may also employ at least one of oxygen (O), nitrogen (N), and silicon (Si) as an additive. In addition, the upper electrode 175 may include a conductive layer such as a titanium nitride (TiN) layer, a titanium aluminum nitride (TiAlN) layer, a tungsten nitride layer (WN2), or a titanium tungsten layer (TiW).

As described above, according to the present invention, the gate electrode 150 of the peripheral area PA determining the height of the PN diode 150 is formed as a single conductive layer and thereby lowers the height of the PN diode 150. Accordingly, the deposition thickness of the epitaxial layer including the PN diode 150 is actually lowered, so that high-temperature SEG processing time is reduced as compared with more conventional processes. Therefore, thermal budget imposed on existing transistors provided in the peripheral area PA is reduced.

In addition, when the ohmic layer of the PN diode 150 is formed, the silicide layer 160 is formed on the gate electrode 125 of the peripheral area PA, so that the conductive characteristic of the gate electrode 125 can be compensated.

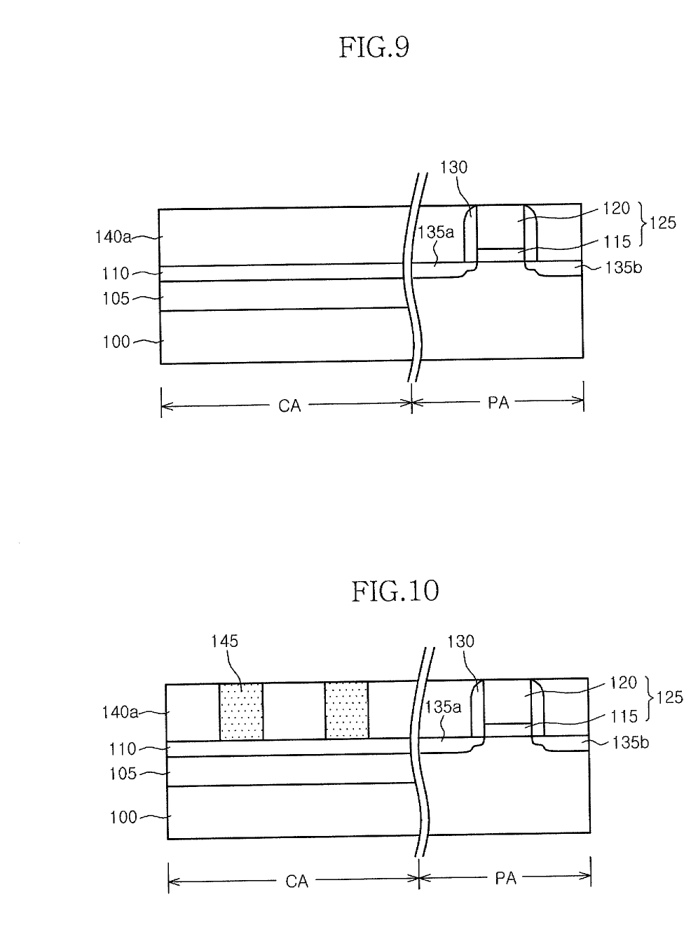

FIGS. 9 and 10 are sectional views showing a method of manufacturing a phase-change random access memory according to another embodiment of the present invention. The present embodiment has manufacturing processes identical to those shown in FIGS. 1 to 3, so the subsequent processes will be described below.

Referring to FIG. 9, the first interlayer dielectric layer 140, which is formed higher than the gate electrode 125 by the predetermined thickness t, is planarized such that the surface of the gate electrode 125 is exposed. The planarization process may be a CMP process. Reference numeral 140a refers to the first interlayer dielectric layer that has been subject to the CMP process.

Referring to FIG. 10, a predetermined portion of the first interlayer dielectric layer 140a is etched such that the junction area 110 is exposed to form a contact hole (not shown). Then the epitaxial layer is grown using the SEG fabrication scheme so that the contact hole is sufficiently filled in with the epitaxial layer. Thereafter, the CMP process is performed so that the only remaining portion of the epitaxial layer remains only in the contact hole.

According to the embodiment, since the epitaxial layer is formed after the depth of the contact hole is lowered corresponding to the height of the gate electrode 125, then the epitaxial layer may be formed with a lower height. Therefore, the high-temperature SEG processing time is shortened which means the high-temperature thermal budget can be reduced. Since the subsequent processes are identical to those of the previous embodiment, details thereof will be omitted in order to avoid redundancy.

The present invention is not limited to the above embodiments. It is understood that the present invention is not limited to these particular exemplary embodiments disclosed and that the present invention can be implemented in any number of various alternate forms which are too numerous to be discussed in detail. These present exemplary embodiments are provided for illustrative purposes to allow one skilled in the art to more easily grasp the essence of the present invention.

Although the epitaxial layer that is not doped with impurities is grown and then n-type and p-type impurities are sequentially implanted into the epitaxial layer according to the present embodiment such that the PN diode is formed, the present invention is not limited thereto. In detail, after the epitaxial layer doped with n-type impurities is grown, p-type impurities are implanted into the epitaxial layer, thereby forming the PN diode.

In addition, the p-type impurities can be implanted into the epitaxial layer in multiple stages to form the PN diode.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A method of manufacturing a phase-change random access memory, the method comprising:
preparing a semiconductor substrate to define a cell area and a peripheral area;
forming a junction area in the cell area;
forming a transistor having a gate electrode including a single conductive layer in the peripheral area;
forming a first interlayer dielectric layer over an upper portion of the semiconductor substrate;
forming a contact hole through the first interlayer dielectric layer by etching selectively the first interlayer dielectric layer such that a predetermined portion of the junction area is exposed; and
growing an epitaxial layer within the contact hole.

2. The method of claim 1, wherein, in the forming of the first interlayer dielectric layer, the first interlayer dielectric layer is deposited at a height greater than the gate electrode by a predetermined thickness.

3. The method of claim 2, wherein the first interlayer dielectric layer is higher than the gate electrode by a thickness of about 100 Å to 2000 Å.

4. The method of claim 1, wherein the forming of the first interlayer dielectric layer includes:
forming the first interlayer dielectric layer higher than the gate electrode at an upper portion of the semiconductor substrate; and
planarizing the first interlayer dielectric layer to expose a surface of the gate electrode.

5. The method of claim 1, further comprising:
planarizing the epitaxial layer to expose a surface of the gate electrode;
forming a PN diode in the epitaxial layer; and
forming a silicide layer over both the PN diode and the gate electrode, after forming the epitaxial layer.

6. The method of claim 5, wherein the forming of the PN diode includes:
forming an n-type diode area by implanting n-type impurities into a lower portion of the epitaxial layer; and
forming a p-type diode area by implanting p-type impurities into an upper portion of the epitaxial layer.

7. The method of claim 5, wherein the forming of the silicide layer includes:
depositing a refractory metal layer over the first interlayer dielectric layer having the PN diode;
allowing the refractory metal layer to react with the PN diode and the gate electrode; and
removing a portion of the refractory metal layer which is not subject to the reaction.

8. The method of claim 5, further comprising:
depositing a second interlayer dielectric layer on a resultant structure of the first interlayer dielectric layer;
forming a through hole through a predetermined portion of the silicide layer to expose the PN diode;
forming a heating electrode within the through hole;
forming a phase-change layer contacting the heating electrode; and
forming an upper electrode over the phase-change layer, after the silicide layer is formed.

9. The method of claim 8, wherein the upper electrode and the phase-change layer are selectively patterned substantially perpendicularly to the junction area after the upper electrode is formed.

10. The method of claim 1, further comprising:
forming a gate insulating layer over an upper portion of the peripheral area;
forming a doped poly-silicon layer over the gate insulating layer; and
patterning a predetermined portion of the doped poly-silicon layer.

11. A method of manufacturing a phase-change memory device, the method comprising:
preparing a semiconductor substrate defining a cell area and a peripheral area;
forming a junction area in the cell area;
forming a transistor having a gate electrode including a single conductive layer in the peripheral area;
forming a first interlayer dielectric layer at an upper portion of the semiconductor substrate;
forming a contact hole by selectively etching through the first interlayer dielectric layer to expose a predetermined portion of the junction area;
growing an epitaxial layer so that the contact hole is filled in with the epitaxial layer;
planarizing the epitaxial layer and the first interlayer dielectric layer to expose a surface of the gate electrode;
forming a PN diode in the epitaxial layer filled in the contact hole; and
forming an ohmic contact layer over the PN diode and a conductivity compensating layer over the gate electrode with a silicide layer over the PN diode and the gate electrode.

12. The method of claim 11, wherein, in the forming of the first interlayer dielectric layer, the first interlayer dielectric layer is deposited higher than the gate electrode by a thickness of about 100 Å to 2000 Å.

13. The method of claim 11, wherein the forming of the first interlayer dielectric layer includes:
forming the first interlayer dielectric layer at a height higher than the gate electrode on the semiconductor substrate; and
planarizing the first interlayer dielectric layer to expose a surface of the gate electrode.

14. The method of claim 11, wherein the epitaxial layer is not doped with impurities.

15. The method of claim 14, wherein the forming of the PN diode includes:
forming an n-type diode area by implanting n-type impurities into a lower portion of the epitaxial layer; and
forming a p-type diode area by implanting p-type impurities into an upper portion of the epitaxial layer.

16. The method of claim 11, wherein the forming of the silicide layer includes:
depositing a refractory metal layer over the first interlayer dielectric layer having the PN diode;
allowing the refractory metal layer to react with the PN diode and the gate electrode; and
removing a portion of the refractory metal layer that did not react.

17. The method of claim 11, further comprising:
depositing a second interlayer dielectric layer over the first interlayer dielectric layer;
forming a through hole through the second interlayer dielectric layer to expose a predetermined portion of the silicide layer on the PN diode;
forming a heating electrode within the through hole;
forming a phase-change layer contacting the heating electrode; and
forming an upper electrode on the phase-change layer, after the silicide layer is formed.

18. The method of claim 11, wherein the upper electrode and the phase-change layer are patterned substantially perpendicularly to the junction area after the upper electrode is formed.

19. The method of claim 11, further comprising:
forming a gate insulating layer at an upper portion of the peripheral area;
forming a doped poly-silicon layer over the gate insulating layer; and
patterning a predetermined portion of the doped poly-silicon layer.

20. A phase-change random access memory comprising:
a semiconductor substrate defining a cell area and a peripheral area;
a junction area formed in the cell area of the semiconductor substrate;
a transistor which includes a gate electrode having a predetermined height and formed in the peripheral area of the semiconductor substrate; and
a PN diode electrically connected with the word line area, wherein the gate electrode includes a single conductive layer, and has a height substantially matching that of the PN diode.

21. The phase-change random access memory of claim 20, further comprises a silicide layer formed on the PN diode and on the gate electrode such that the silicide layer has an substantially identical thickness on the PN diode and the gate electrode.

22. The phase-change random access memory of claim 21, further comprising an interlayer dielectric layer interposed between adjacent PN diodes and between the PN diode and the gate electrode such that the interlayer dielectric layer has a height substantially matching a height of a surface of the silicide layer.
